(19) United States
(12) Patent Application Publication
(10) Pub. No.: US 2009/0219418 A1
(43) Pub. Date: Sep. 3, 2009

(54) IMAGE SENSOR AND METHOD TO REDUCE DARK CURRENT OF CMOS IMAGE SENSOR

(76) Inventor: Hiroaki Fujita, Rochester, NY (US)

Correspondence Address: F-P, Patent Legal Staff;Eastman Kodak Company, 343 State Street, Rochester, NY, 14650-2201, US

(21) Appl. No.: 12/039,798

(22) Filed: Feb. 29, 2008

(51) Int. Cl. H04N 5/217; H01L 27/146

(52) U.S. Cl. 348/243; 250/208.1; 257/E27.133; 348/E05.081

(57) ABSTRACT

An image sensor includes one or more photodetectors for collecting charge in response to incident light and a storage region adjacent each photodetector. A transfer mechanism transfers charge from each photodetector to a respective storage region. A conductive layer or a polysilicon layer is situated over each storage region. A bias voltage terminal is connected to each conductive layer or polysilicon layer for receiving a bias voltage to bias the conductive layer or polysilicon layer to a predetermined voltage level.

### FIELD OF THE INVENTION

The invention relates generally to the field of image sensors, and more particularly, to reducing dark current in CMOS image sensors with global shutter.

### BACKGROUND OF THE INVENTION

A typical image sensor includes a substrate having a photosensitive area or charge collection area for collecting charge, and a transfer gate for transferring charge from the photosensitive area to either a charge-to-voltage conversion mechanism, such as a floating diffusion in a CMOS image sensor, a transfer mechanism in a charge-coupled device image sensor or to a reset mechanism. A dielectric is positioned between the gate and the substrate, and the area of contact between the two areas is generally referred to as the semiconductor/dielectric interface.

“Dark current” is a limitation of the performance of such image sensors. During certain stages of image capture, such as integration, electrons not associated with the photosensitive process that captures the electronic representation of the image (the photo-generation process), accumulate in certain portions of the sensor, such as adjacent gates, and inherently migrate into the photosensitive area. These electrons are undesirable as they degrade the quality of the captured image.

CMOS image sensors with a global shutter, such as a CMOS image sensor for automobile, security, digital single lens reflex cameras, etc., have a memory cell for each pixel of the array to realize the global shutter. The memory cell includes a light shield to prevent light from coming in while the memory cell holds charges. Unfortunately, the light shield-silicon interface becomes a source of dark current.

### SUMMARY OF THE INVENTION

The present invention is directed to overcoming one or more of the problems set forth above. Briefly summarized, according to one aspect of the present invention, an image sensor includes one or more photodetectors for collecting charge in response to incident light and a storage region adjacent each photodetector. A transfer mechanism transfers charge from each photodetector to a respective storage region. Another transfer mechanism transfers the charge from one or more storage regions to a sense node, where each sense node converts the charge to a voltage signal.

A conductive layer or a polysilicon layer is situated over each storage region. A bias voltage terminal is connected to each conductive layer or polysilicon layer for receiving a bias voltage to bias the conductive layer or polysilicon layer to a predetermined voltage level. A negative bias voltage is applied if the one or more photodetectors are electron detectors, and a positive bias is applied if the one or more photodetectors are hole detectors. The bias voltage biases the conductive layer or the polysilicon layer at a voltage level that causes minority carriers to accumulate at the top surface of each storage region.

These and other aspects, objects, features and advantages of the present invention will be more clearly understood and appreciated from a review of the following detailed description of the preferred embodiments and appended claims, and by reference to the accompanying drawings.

### Advantageous Effect Of The Invention

The present invention has the advantage of reducing dark current in image sensors.

### BRIEF DESCRIPTION OF THE DRAWINGS

FIG. 1 is a block diagram conceptually illustrating portions of an image sensor in accordance with an embodiment of the present invention;

FIG. 2 is a block diagram conceptually illustrating portions of an image sensor in accordance with a further embodiment of the present invention;

FIG. 3 is a schematic diagram illustrating portions of an image sensor in accordance with an embodiment of the present invention;

FIG. 4 is a schematic diagram illustrating portions of an image sensor in accordance with another embodiment of the present invention;

FIG. 5 is a schematic diagram illustrating portions of an image sensor in accordance with a further embodiment of the present invention;

FIG. 6 is a timing diagram illustrating operation of an image sensor in accordance with embodiments of the present invention; and

FIG. 7 is a block diagram of an exemplary image capture device that employs an image sensor in an embodiment in accordance with the invention.

### DETAILED DESCRIPTION OF THE INVENTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting.

The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal. Identical reference numerals have been used, where possible, to designate identical elements that are common to the figures.

It is to be understood that other embodiments may be utilized and structural or logical changes may be made without departing from the scope of the present invention. The following detailed description, therefore, is not to be taken in a limiting sense, and the scope of the present invention is defined by the appended claims.

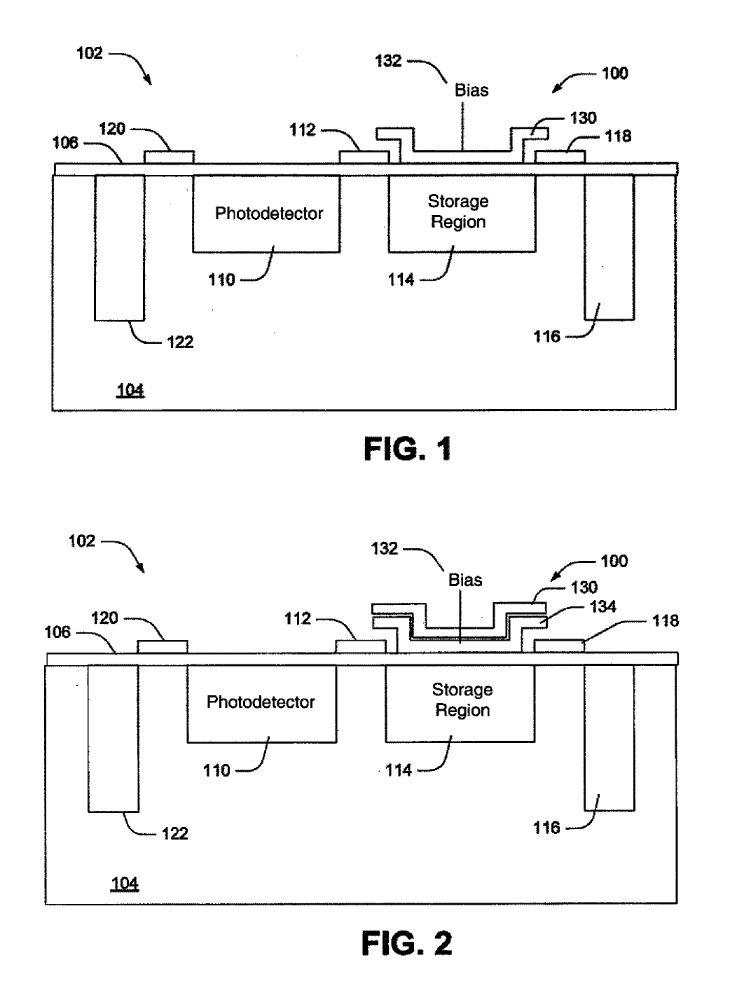

Referring to FIG. 1, portions of an image sensor 100 in accordance with embodiments of the invention are conceptually illustrated. The image sensor 100 is implemented as a Complementary Metal Oxide Semiconductor (CMOS) image sensor in the embodiment shown in FIG. 1. A typical image sensor includes a plurality of pixels, which usually are arranged in an array of rows and columns. For simplicity, FIG. 1 illustrates a single exemplary pixel 102 in accordance with aspects of the present invention. The image sensor 100 includes a substrate 104, with an insulator 106 situated on the substrate. The pixel 102 includes a photodetector 110 and a transfer mechanism 112 for transferring charge to a storage region 114.

The photodetector 110 receives incident light and consequently converts the incident light into charge packets. The photodetector 110 is implemented as a pinned photodiode in an embodiment in accordance with the invention. A first transfer mechanism 112, such as transfer gate, is separated from the substrate 102 by the insulator 106 and functions to transfer charge from the photodetector 110 to the storage region 114 adjacent the photodetector 110. In the illustrated embodiment, the storage region 114 is a MOS memory cell.

A sense node 116 receives the charge from the storage region 114 and converts the charge to a voltage signal. The sense node 116 is implemented as a floating diffusion in an embodiment in accordance with the invention. A second transfer mechanism 118, such as a transfer gate, transfers the charge from the storage region 114 to the sense node 116. In the illustrated embodiment, an overflow gate 120 and overflow drain 122 are situated adjacent the photodetector 110, opposite the first transfer mechanism 112.

A conductive layer 130, such as a light shield, is situated over the storage region 114, and the conductive layer 130 includes a bias voltage terminal 132 connected thereto for receiving a bias voltage. The bias voltage biases the conductive layer 130 at a voltage level that causes minority carriers to accumulate at the top surface of the storage region 114. When the storage region 114 stores charge, this accumulation of minority carriers reduces dark current at the semiconductor-dielectric interface of the storage region 114. A negative bias is applied if the majority carriers are electrons, and a positive bias is applied if the majority carriers are holes. Typical bias voltage levels in exemplary embodiments are −1 volt for a negative bias and +4 volts for a positive bias.

An alternative embodiment is illustrated in FIG. 2, which includes a polysilicon layer, or “poly gate” 134 between the conductive layer 130 and the storage region 114. In the embodiment illustrated in FIG. 2, the bias voltage 132 is applied to the poly gate 134, rather than the conductive layer 130. The bias voltage biases the poly gate 134 at a voltage level that causes minority carriers to accumulate at the top surface of the storage region 114. As with the embodiment illustrated in FIG. 1, a negative bias is applied if the majority carriers are electrons, and a positive bias is applied if the majority carriers are holes.

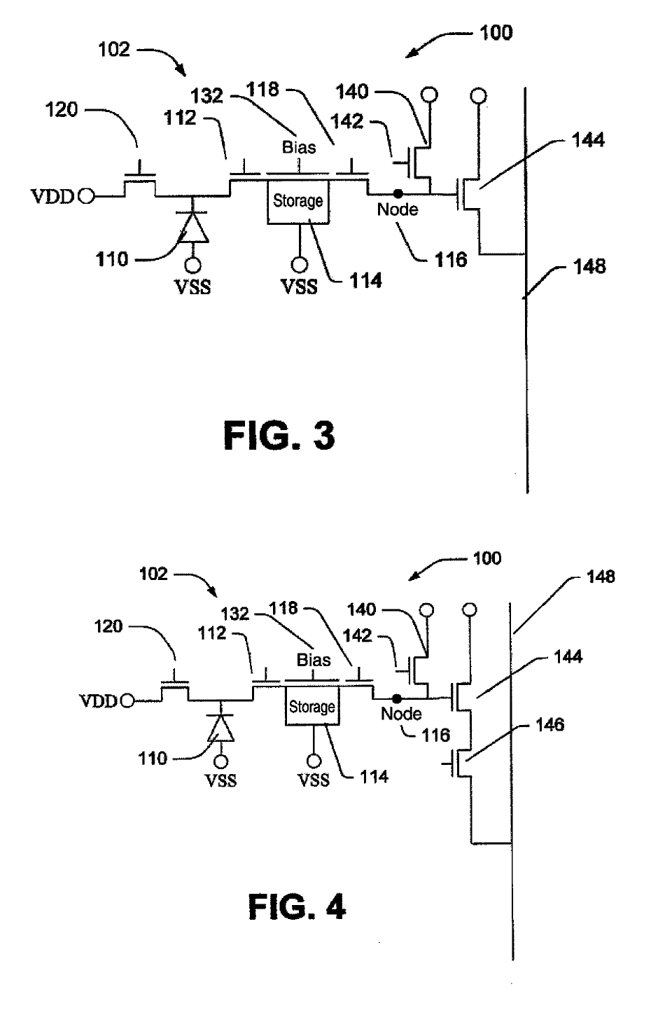

FIG. 3 is a schematic diagram illustrating further aspects of an exemplary image sensor 100. A reset transistor 140 includes a reset gate (RG) 142. The source of the reset transistor is the sense node 116, which is also the input to an amplifier 144, such as a source follower transistor. As noted above, the pixel 102 is typically part of a pixel array. The embodiment illustrated in FIG. 4 further includes a row select (RSEL) transistor 146 connected to a column bus 148. The readout of charge from the pixels in an array is typically accomplished by selecting the desired row of the array by activating the proper row select (SEL) transistor 146, and then reading out the information from the pixels in the selected row.

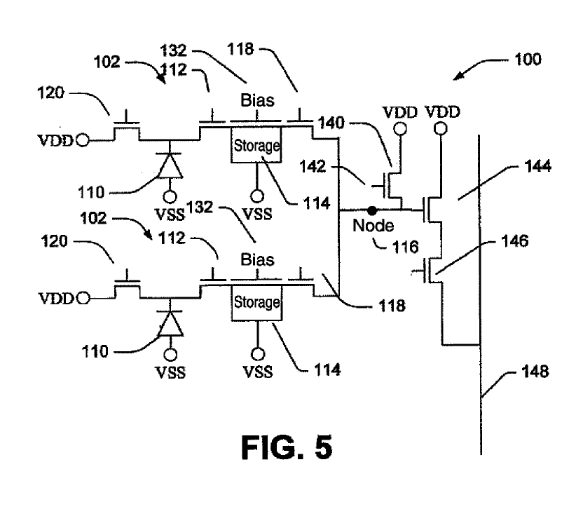

In the embodiment of FIG. 5, a “shared” arrangement is illustrated, in which a plurality (two in the illustrated embodiment) of pixels 102 share the input to the sense node 116 and amplifier 144.

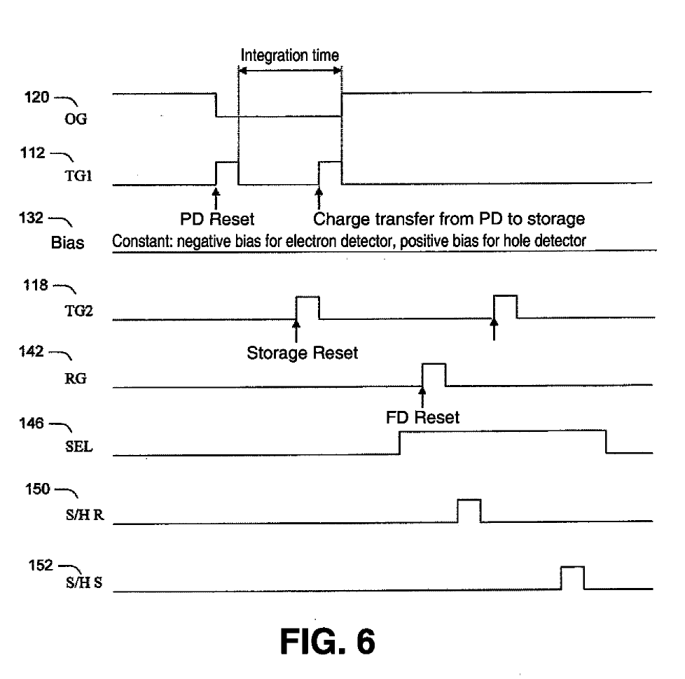

FIG. 6 is a timing diagram, illustrating operation of an embodiment of an image sensor in accordance with the present invention. The first transfer mechanism (TG1) 112 is pulsed to reset the photodetector 110, and the overflow gate (OG) 120 is taken low. The second transfer mechanism (TG2) 118 is pulsed to reset the storage region 114, and the first transfer mechanism (TG1) 112 is pulsed again at the end of a desired integration time of the photodetector 110 to transfer charge from the photodetector 110 to the storage region 114. The row select (RSEL) transistor 146 is activated to select the desired row, and the reset gate (RG) 142 is pulsed to reset the sense node 116. After resetting the sense node 116, a sample/hold reset (S/H R) signal 150 is pulsed and the second transfer gate (TG2) 118 is pulsed to initiate the charge transfer from the storage region 114 to the sense node 116, followed by pulsing a sample/hold set (S/H S) signal 152.

The bias voltage 132 applied to the conductive layer 130 or poly gate 134 is continuously held at a constant level in an embodiment in accordance with the invention to accumulate majority carriers and thus, reduce dark current. A negative bias voltage is applied if the photodetector 110 is an electron detector, and a positive bias is applied if it is a hole detector. The bias voltage can be applied differently in other embodiments in accordance with the invention. For example, the bias voltage 132 can be applied to the conductive layer 130 or poly gate 134 and held at a constant level only when charge is stored in storage region 114.

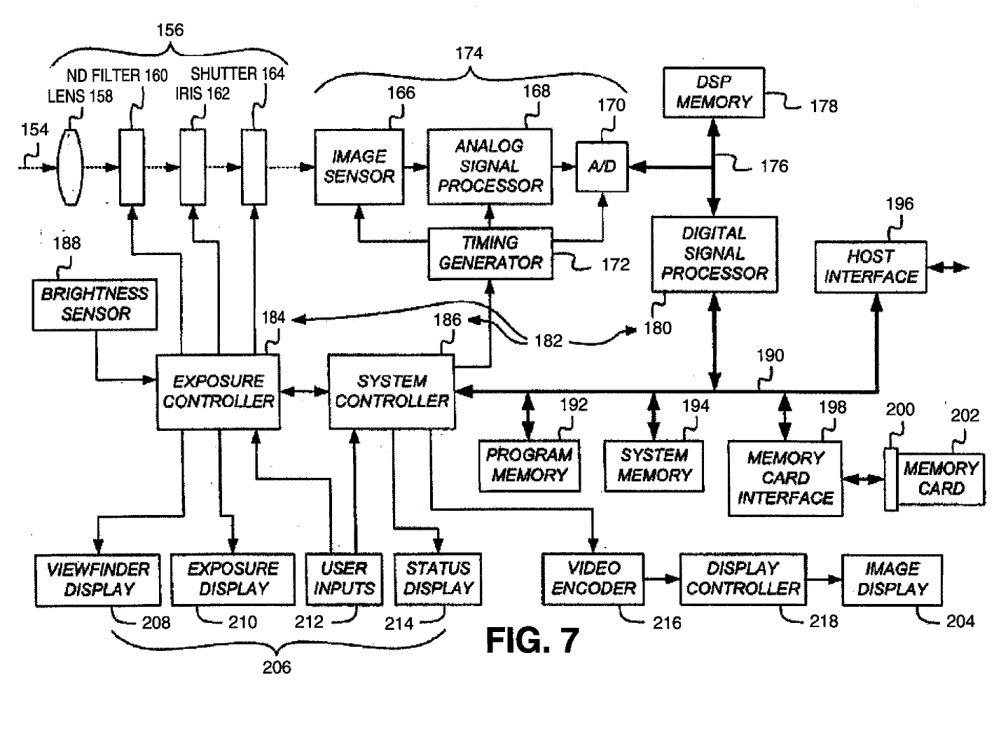

FIG. 7 is a block diagram of an exemplary image capture device that employs an image sensor in an embodiment in accordance with the invention. The image capture device is implemented as a digital camera in the embodiment shown in FIG. 7. Light 154 from a subject scene is input to an imaging stage 156. The imaging stage 156 comprises lens 158, neutral density (ND) filter 160, iris 162 and shutter 164. The light 154 is focused by lens 158 to form an image on an image sensor 166. The amount of light reaching the image sensor 166 is regulated by iris 162, ND filter 160 and the time that shutter 164 is open. The image sensor 166 converts the incident light to an electrical signal for each pixel. The image sensor 166 may be, for example, an active pixel sensor (APS) type image sensor, although other types of image sensors may be used in implementing the invention. APS type image sensors fabricated using a complementary metal-oxide-semiconductor (CMOS) process are often referred to as CMOS image sensors.

The image sensor 166 typically has a two-dimensional array of pixels configured in accordance with a designated CFA pattern (not shown). Examples of CFA patterns that may be used with the image sensor 166 include the panchromatic checkerboard patterns disclosed in U.S. Patent Application Publication No. 2007/0024931, entitled “Image Sensor with Improved Light Sensitivity.” These panchromatic checkerboard patterns provide certain of the pixels with a panchromatic photoresponse, and are also generally referred to herein as “sparse” CFA patterns. A panchromatic photoresponse has a wider spectral sensitivity than those spectral sensitivities represented in the selected set of color photoresponses and may, for example, have high sensitivity across substantially the entire visible spectrum. Image sensors configured with panchromatic checkerboard CFA patterns exhibit greater light sensitivity and are thus well suited for use in applications involving low scene lighting, short exposure time, small aperture, or other restrictions on the amount of light reaching the image sensor. Other types of CFA patterns may be used in other embodiments of the invention.

An analog signal from image sensor 166 is processed by analog signal processor 168 and applied to analog to digital (A/D) converter 170. Timing generator 172 produces various clocking signals to select particular rows and columns of the pixel array for processing, and synchronizes the operation of analog signal processor 168 and A/D converter 170. The image sensor 166, analog signal processor 168, A/D converter 170, and timing generator 172 collectively form an image sensor stage 174 of the camera. The components of the image sensor stage 174 may comprise separately fabricated integrated circuits, or they may be fabricated as a single integrated circuit as is commonly done with CMOS image sensors. The A/D converter 170 outputs a stream of digital pixel values that are supplied via a bus 176 to a memory 178 associated with a digital signal processor (DSP) 180. Memory 178 may comprise any type of memory, such as, for example, synchronous dynamic random access memory (SDRAM). The bus 176 provides a pathway for address and data signals and connects DSP 180 to memory 178 and A/D converter 170.

The DSP 180 is one of a plurality of processing elements of the camera that are indicated as collectively comprising a processing stage 182. The other processing elements of the processing stage 182 include exposure controller 184 and system controller 186. Although this partitioning of device functional control among multiple processing elements is typical, these elements may be combined in various ways without affecting the functional operation of the image capture device and the application of the present invention. A given one of the processing elements of processing stage 182 can comprise one or more DSP devices, microcontrollers, programmable logic devices, or other digital logic circuits. Although a combination of three separate processing elements is shown in the figure, alternative embodiments may combine the functionality of two or more of these elements into a single processor, controller or other processing element. Techniques for sampling and readout of the pixel array of the image sensor 166 may be implemented at least in part in the form of software that is executed by one or more such processing elements.

The exposure controller 184 is responsive to an indication of an amount of light available in the scene, as determined by brightness sensor 188, and provides appropriate control signals to the ND filter 160, iris 162 and shutter 164 of the imaging stage 156.

The system controller 186 is coupled via a bus 190 to DSP 180 and to program memory 192, system memory 194, host interface 196 and memory card interface 198. The system controller 186 controls the overall operation of the camera based on one or more software programs stored in program memory 192, which may comprise Flash electrically erasable programmable read-only memory (EEPROM) or other nonvolatile memory. This memory is also used to store image sensor calibration data, user setting selections and other data which must be preserved when the camera is turned off. System controller 186 controls the sequence of image capture by directing exposure controller 184 to operate the lens 158, ND filter 169, iris 162, and shutter 164 as previously described, directing the timing generator 172 to operate the image sensor 166 and associated elements, and directing DSP 180 to process the captured image data.

In the illustrated embodiment, DSP 180 manipulates the digital image data in its memory 178 according to one or more software programs stored in program memory 192 and copied to memory 178 for execution during image capture. After an image is captured and processed, the resulting image file stored in memory 178 may be, for example, transferred via host interface 196 to an external host computer, transferred via memory card interface 198 and memory card socket 200 to removable memory card 202, or displayed for the user on an image display 204. The image display 204 is typically an active matrix color liquid crystal display (LCD), although other types of displays may be used.

The camera further includes a user control and status interface 206 including a viewfinder display 208, an exposure display 210, user inputs 212 and status display 214. These elements may be controlled by a combination of software programs executed on exposure controller 184 and system controller 186. The user inputs 212 typically include some combination of buttons, rocker switches, joysticks, rotary dials or touchscreens. Exposure controller 184 operates light metering, exposure mode, auto-focus and other exposure functions. The system controller 186 manages a graphical user interface (GUI) presented on one or more of the displays, e.g., on image display 204. The GUI typically includes menus for making various option selections and review modes for examining captured images.

Processed images may be copied to a display buffer in system memory 194 and continuously read out via video encoder 216 to produce a video signal. This signal may be output directly from the camera for display on an external monitor, or processed by display controller 218 and presented on image display 204.

It is to be appreciated that the image capture device as shown in FIG. 7 may comprise additional or alternative elements of a type known to those skilled in the art. Elements not specifically shown or described herein may be selected from those known in the art. As noted previously, the embodiments in accordance with the invention may be implemented in a wide variety of other types of image capture devices. For example, the present invention can be implemented in imaging applications involving mobile phones and automotive vehicles. Also, as mentioned above, certain aspects of the embodiments described herein may be implemented at least in part in the form of software executed by one or more processing elements of an image capture device. Such software can be implemented in a straightforward manner given the teachings provided herein, as will be appreciated by those skilled in the art.

The invention has been described with reference to two embodiments in accordance with the invention. However, it will be appreciated that a person of ordinary skill in the art can effect variations and modifications without departing from the scope of the invention.

### PARTS LIST

110 photodetector
112 first transfer mechanism
114 storage region
116 sense node
118 second transfer mechanism
120 overflow gate
122 overflow drain
130 conductive layer
132 bias voltage terminal
134 poly gate
140 reset transistor
142 reset gate
144 amplifier
146 row select
148 column bus
150 sample/hold reset
152 sample/hold set
154 light
156 imaging stage
158 lens
160 ND filter
162 iris
164 shutter
166 image sensor
168 analog signal processor
170 A/D converter
172 timing generator
174 image sensor stage
176 bus
178 memory
180 digital signal processor
182 processing stage
184 exposure controller
186 system controller
188 brightness sensor
190 bus
192 program memory
194 system memory
196 host interface
198 memory card interface
200 memory card socket
202 removable memory card
204 display
206 user control and status interface
208 viewfinder display
210 exposure display
212 user input
214 status display
216 video encoder
218 display controller

1. An image sensor comprising:
a photodetector for collecting charge in response to incident light;
a storage region adjacent the photodetector;
a first transfer mechanism for transferring charge from the photodetector to the storage region;
a conductive layer situated over the storage region; and
a bias voltage terminal connected to the conductive layer for receiving a bias voltage to bias the conductive layer to a predetermined voltage level.

2. The image sensor as in claim 1, further comprising:
a sense node adjacent the storage region; and
a second transfer mechanism that transfers the charge from the storage region to the sense node, wherein the sense node converts the charge to a voltage signal.

3. The image sensor as in claim 2, further comprising an amplifier for receiving the voltage signal from the sense node.

4. The image sensor as in claim 2, wherein the first transfer mechanism includes a first transfer gate for transferring charge from the photodetector to the storage region and the second transfer mechanism includes a second transfer gate for transferring charge from the storage region to the sense node.

5. The image sensor as in claim 1, wherein the collected charges are electrons, and wherein the bias terminal is connected to a negative bias voltage.

6. The image sensor as in claim 1, wherein the collected charges are holes, and wherein the bias terminal is connected to a positive bias voltage.

7. The image sensor as in claim 3, further comprising a plurality of pixels, each pixel including the photodetector, the first transfer mechanism and the storage region, and wherein the sense node, the second transfer mechanism, and an input to the amplifier are shared by a subset of pixels.

8. The image sensor as in claim 1, wherein the conductive layer is a light shield.

9. The image sensor as in claim 8, further comprising a polysilicon layer disposed between the conductive layer and the storage region; wherein the bias voltage terminal is configured to apply the bias voltage to the polysilicon layer.

10. The image sensor as in claim 1, further comprising an overflow drain adjacent the photodetector.

11. The image sensor as in claim 1, wherein the photodetector is a pinned photodiode.

12. A method of operating an image sensor, comprising:
resetting a photodetector, a storage region, and a sense node to set a potential charge value in the photodetector, the storage region, and the sense node to a predetermined reset level;
applying a bias voltage to the storage region to accumulate minority carriers at a surface of the storage region;
exposing the photodetector to light to accumulate a charge comprised of majority carriers; and
transferring the charge comprised of majority carriers to the storage region, wherein the accumulated minority carriers at the surface of the storage region reduce dark current generation.

13. The method of claim 12, further comprising transferring the charge in the storage region to the sense node where the charge comprised of majority carriers is converted to a voltage.

14. The method of claim 13, further comprising transferring the voltage from the sense node to an input of an amplifier.

15. The method of claim 14, wherein transferring the charge in the storage region to the sense node includes transferring the charges from a plurality of storage regions to a common sense node.

16. The method of claim 12, wherein applying the bias voltage to the storage region includes applying a negative voltage.

17. The method of claim 12, wherein applying the bias voltage to the storage region includes applying a positive voltage.

18. The method of claim 12, wherein applying a bias voltage to the storage region to accumulate minority carriers at a surface of the storage region includes applying a bias voltage to a conductive layer situated above the storage region to accumulate minority carriers at a surface of the storage region.

19. The method of claim 12, wherein applying a bias voltage to the storage region to accumulate minority carriers at a surface of the storage region includes applying a bias voltage to a polysilicon layer positioned between a conductive layer and the storage region to accumulate minority carriers at a surface of the storage region.

20. An image capture device, comprising:
an image sensor including an array of pixels, each pixel including:
a photodetector for collecting charge in response to incident light;
a storage region adjacent the photodetector;
a transfer mechanism for transferring charge from the photodetector to the storage region;
a conductive layer situated over the storage region; and
a bias voltage terminal connected to the conductive layer for receiving a bias voltage to bias the conductive layer to a predetermined voltage level.

21. The image capture device as in claim 20, further comprising a sense node adjacent the storage region for receiving the charge from the storage region and converting the charge to a voltage signal.

22. The image capture device as in claim 21, wherein the sense node receives the charge from the storage regions of a plurality of pixels.
